(19) United States
(12) Patent Application Publication
(10) Pub. No.: US 2016/0084865 A1
(43) Pub. Date: Mar. 24, 2016

(54) INTEGRATED ROTATION RATE AND ACCELERATION SENSOR AND METHOD FOR MANUFACTURING AN INTEGRATED ROTATION RATE AND ACCELERATION SENSOR

(71) Applicant: ROBERT BOSCH GMBH, Stuttgart (DE)

(72) Inventors: Arnd Kaelberer, Schlierbach (DE); Jochen Reinmuth, Reutlingen (DE); Johannes Classen, Reutlingen (DE)

(21) Appl. No.: 14/890,527

(22) PCT Filed: May 5, 2014
(86) PCT No.: PCT/EP2014/059060

§ 371 Date: Nov. 11, 2015

(30) Foreign Application Priority Data
May 14, 2013 (DE) 10 2013 208 814.0

(51) Int. Cl. G01P 1/00; G01C 19/56; G01P 15/02; B81C 1/00

(52) U.S. Cl. CPC G01P 1/00; B81C 1/00301; G01C 19/56; G01P 15/02

(57) ABSTRACT

A micromechanical device having a main plane of extension includes a sensor wafer, an evaluation wafer, and an intermediate wafer situated between the sensor wafer and the evaluation wafer, the evaluation wafer having at least one application-specific integrated circuit. The sensor wafer and/or the intermediate wafer includes a first sensor element and a second sensor element spatially separated from the first sensor element, the first and second sensor elements being respectively located in a first cavity and a second cavity each formed by the intermediate wafer and the sensor wafer, a first gas pressure in the first cavity differing from a second gas pressure in the second cavity, and the intermediate wafer having an opening at a point in a direction perpendicular to the main plane of extension.

### BACKGROUND OF THE INVENTION

1. Field of the Invention

The present invention relates to a micromechanical device, which includes at least two sensor elements, an evaluation wafer, and at least two cavities having different gas pressures.

2. Description of the Related Art

Such a micromechanical device is known, for example, from the published German patent application document DE 102006016260 A1 and allows multiple different sensor systems, having different requirements for the atmosphere surrounding them, to be combined in one micromechanical device. The different sensor systems, typically an acceleration sensor and a rotation rate sensor, are situated in different cavities and include a sensor element, preferably a seismic mass. For such micromechanical devices, it is generally provided that the different sensor systems are manufactured at the same time, i.e., in one method step, on a substrate, whereby particularly small and cost-effective combinations of different sensor systems are implementable in one single micromechanical device. The technical requirement exists for the affected micromechanical devices that the sensor systems are to be operated under the gas pressure provided in each case for them, which is different in most cases. Specifically, for example, while a preferably low gas pressure (approximately 1 mbar) is desirable for a rotation rate sensor, so that the resonant driven seismic mass of the rotation rate sensor only experiences a slight damping, acceleration sensors are preferably operated at a gas pressure which is approximately 500 times higher. The related art typically uses getter materials to set the desired gas pressure, which differs from cavity to cavity. This getter material is, for example, introduced into the cavity for which a lower pressure is provided, and is capable in an activated state of capturing gas molecules, whereby the gas pressure in the cavity is reduced. The getter material is typically activated in that the temperature exceeds a threshold value. The use of additional getter materials, which are therefore linked to additional costs, during the production of the micromechanical device has proven to be a disadvantage.

In addition, it is desirable to dimension the electrical connection between the sensor system and the evaluation circuit in such a way that the micromechanical device is not enlarged further and the electrical signal path between sensor system and evaluation circuit is preferably short. If the relevant electrical connection is selected to be excessively large, it is therefore to be expected that interfering influences may act from the outside on the signal path and worsen the signal-to-noise ratio. It is therefore the object of the present invention to provide a micromechanical device and a cost-effective method for manufacturing a micromechanical device, the micromechanical device having at least two cavities having different gas pressures. The present invention is additionally directed to providing a micromechanical device, in which the sensor system is connected to the evaluation circuit via a very short, electrically conductive signal path.

### BRIEF SUMMARY OF THE INVENTION

The object is achieved by a micromechanical device including a sensor wafer, at least one intermediate wafer, and an evaluation wafer, the micromechanical device having a main plane of extension, the sensor wafer, the intermediate wafer, and the evaluation wafer being stacked in such a way that the intermediate wafer is situated between the sensor wafer and the evaluation wafer. In general, multiple such micromechanical devices are manufactured in a shared manufacturing process, intermediate wafer, sensor wafer, and evaluation wafer extending over all micromechanical devices to be produced during the manufacturing process.

It is additionally provided according to the present invention that the evaluation wafer is an ASIC wafer, i.e., the evaluation wafer has an application-specific integrated circuit, which is provided to process or relay the items of information originating from the sensor wafer in the form of electrical signals.

Furthermore, it is provided according to the present invention that the sensor wafer and/or the intermediate wafer include(s) a first sensor element, preferably a first seismic mass of an acceleration sensor or a rotation rate sensor, and the sensor wafer and/or the intermediate wafer include(s) a second sensor element, which is spatially separated from the first sensor element, preferably a second seismic mass of an acceleration sensor or a rotation rate sensor. It is provided that the first sensor element is located in a first cavity, which is formed by the intermediate wafer and the sensor wafer, and the second sensor element is located in a second cavity, which is formed by the intermediate wafer and the sensor wafer. In particular, it is provided that the sensor element or the first seismic mass and the second seismic mass include electrodes which interact together with one or multiple further electrodes attached to the intermediate wafer and/or the sensor wafer, and therefore form a sensor system or a rotation rate sensor or acceleration sensor.

Furthermore, it is provided according to the present invention that a first gas pressure in the first cavity differs from a second gas pressure in the second cavity, and the intermediate wafer has at least one opening. It is provided that this opening is then part of an intermediate space, which is delimited both by the intermediate wafer and also by the evaluation wafer and also by the sensor wafer. Such an opening may expose the view from the evaluation wafer to the sensor wafer in a direction extending perpendicularly to the main plane of extension, for example. In an alternative specific embodiment, the opening may also, however, expose the view from the evaluation wafer to the sensor wafer if the viewing direction does not extend perpendicularly to the main plane of extension, but rather is inclined at an angle thereto (i.e., at an angle to the direction extending perpendicularly to the main plane of extension), the angle being less than 90°. In particular, the provided opening of the intermediate wafer is capable of delimiting individual subregions of the intermediate wafer from one another. The micromechanical device according to the present invention has proven to be advantageous in relation to those from the related art in that the micromechanical device does not have getter material and therefore the additional costs arising due to the getter material are avoided. In one preferred specific embodiment, the intermediate wafer has convexities, on the side facing toward the sensor wafer, in the area of the first and/or the second cavity, to guarantee or provide a certain movement freedom to the sensor element. In one particularly preferred specific embodiment, it is provided that the micromechanical device has multiple intermediate wafers. In addition, it is provided for another specific embodiment of the present invention that the evaluation wafer has a thickness of 30 μm-150 μm. Using such a thin evaluation wafer it is possible to design the sensor wafer as sufficiently thick that occurring mechanical stresses (for example, induced by different thermal expansions between the micromechanical device and a circuit board on which the micromechanical device is situated) advantageously do not have an effect on the sensor element, because the sensor element is anchored in the thick (150 μm-1000 μm) and stable sensor wafer.

In another specific embodiment of the present invention, it is provided that at least one opening of the intermediate wafer is situated between the evaluation wafer and the second cavity.

In one particularly preferred specific embodiment of the present invention, it is provided according to the present invention that the intermediate wafer is made of an electrically conductive material, preferably a monocrystalline silicon wafer having a high level of doping (boron, phosphorus, arsenic, or antimony). In addition, it is possible that the intermediate layer includes one or multiple coatings. Using such a conductive intermediate wafer for the micromechanical device, it advantageously results that the micromechanical device, thanks to the openings in the intermediate wafer, has signal paths, i.e., electrically conductive connecting parts, which are independent of one another. The signal paths may also extend partially through the second cavity. Electrical signals may be transmitted with the aid of the signal paths from the sensor wafer to the evaluation wafer (preferably for evaluating the signals from the sensor system) or from the evaluation wafer to the sensor wafer (for example, to drive the seismic mass). It thus results that the signal path between evaluation wafer and sensor wafer is short in comparison to those which are known from the related art for micromechanical devices. In a particularly advantageous way, an electrically conductive signal path is thus implemented, which is less susceptible to interference in relation to electromagnetic radiation and parasitic capacitances in comparison to those micromechanical devices in which the electrical signals are transmitted via a longer signal path. In addition, the short signal paths contribute to the micromechanical device being able to be dimensioned as small as possible.

In another specific embodiment of the present invention, it is provided that a first atmosphere or a first gas or a first gas mixture in the first cavity differs from a second atmosphere or a second gas or a second gas mixture. The advantage thus results for the micromechanical device that optimum operating conditions provided for the first and/or second sensor elements may be set not only via the first and/or the second gas pressure, but may also be set by the first and/or second gas or gas mixture located in the first and second cavities. This could prove to be advantageous in particular if it is shown that the gas or gas mixture which is optimum or provided for the operation of the first sensor element in the first cavity is disadvantageous for the operation of the second sensor element in the second cavity (for example, because it has an unfavorable viscosity for the second sensor element in the second cavity).

In another specific embodiment of the present invention, it is provided that the first sensor element is a part or component of an acceleration sensor and the second sensor element is a part or component of a rotation rate sensor. The possibility thus advantageously results of combining a sensor which analyzes a translational movement and a sensor which analyzes a rotational movement in a single micromechanical device. It is similarly possible that the first sensor element is a part or component of a rotation rate sensor and the second sensor element is a part or component of an acceleration sensor.

In another specific embodiment of the present invention, it is provided that one or multiple sensor means are provided on the intermediate wafer, i.e., between the evaluation wafer and the sensor wafer. The sensor means may include a further sensor element or passive elements, for example, a capacitance, a coil, or a diode. In particular, such passive elements are provided there where they are to be protected from influences such as moisture and/or electrical fields. In one preferred specific embodiment of the present invention, the sensor means include a magnetic field sensor, which is situated on the intermediate wafer. The advantage thus results for the micromechanical device of including still more modules, for which an independent device would otherwise be required. Space may thus be saved, for example, on a chip carrier or a circuit board, on which the micromechanical device is situated together with other modules. In addition, it has proven to be an advantage that the sensor means is protected from moisture and electrical fields by the arrangement between evaluation wafer and intermediate wafer.

In another specific embodiment of the present invention, one or multiple stops are provided in the first and/or the second cavity. Such stops, which are preferably situated at defined points above the sensor element, advantageously allow the movement freedom of the first and/or the second sensor element (in particular the first and/or the second seismic mass) to be restricted, for example, to prevent spring fractures of the sensor element in the event of overload. In one alternative specific embodiment, it is provided that the first and/or the second sensor element has/have an anti-adhesive layer, in particular an organic anti-adhesive layer. Such a layer advantageously prevents the sensor elements from sticking to one another in the event of overload. In addition it is possible in another specific embodiment that the first and/or second cavity has/have both a stop and an anti-adhesive layer.

In another specific embodiment of the present invention, it is provided that the sensor wafer and/or evaluation wafer include(s) printed conductors, the sensor wafer having one or multiple first printed conductor(s) and the evaluation wafer having one or multiple second printed conductor(s). Together with the signal paths, which the intermediate wafer provides, the micromechanical device is advantageously capable of sending electrical signals directly from the sensor system of the sensor wafer to the integrated circuit of the evaluation wafer or vice versa, the intermediate wafer ensuring that at least one first printed conductor of the sensor wafer is electrically conductively connected to at least one second printed conductor of the evaluation wafer.

In another preferred specific embodiment of the present invention, it is provided that, on the evaluation wafer, an electrical terminal is situated on the side of the evaluation wafer facing toward the intermediate wafer or on the side facing away from the intermediate wafer. Such an electrical terminal is provided to connect the micromechanical device to the circuit board or the chip carrier. If the terminal is located on the side facing away from the intermediate wafer in particular, it is possible to use the micromechanical device in a bare die structure. In the bare die structure, the micromechanical device may be soldered directly onto the circuit board, whereby further packaging (for example, mold packaging), which is therefore linked to additional costs, of the micromechanical device may advantageously be omitted.

Another object of the present invention is a method for manufacturing a micromechanical device including a sensor wafer, an intermediate wafer, and an evaluation wafer, the micromechanical device having a main plane of extension, the sensor wafer, the intermediate wafer, and the evaluation wafer being stacked in such a way that the intermediate wafer is situated between the sensor wafer and the evaluation wafer, the evaluation wafer having at least one application-specific integrated circuit, and the sensor wafer and/or the intermediate wafer including a first sensor element and the sensor wafer and/or the intermediate wafer including a second sensor element, which is spatially separated from the first sensor element, the first sensor element being located in a first cavity, which is formed by the intermediate wafer and the sensor wafer, and the second sensor element being located in a second cavity, which is formed by the intermediate wafer and the sensor wafer, a first gas pressure in the first cavity differing from a second gas pressure in the second cavity, and the intermediate wafer having at least one opening in a direction perpendicular to the main plane of extension, the sensor wafer and the intermediate wafer being connected to one another by a first connection step and the intermediate wafer and the evaluation wafer being connected to one another by a second connection step, during the first connection step, the first gas pressure of a first gas or first gas mixture in the first cavity being set and, during the second connection step, the second gas pressure of a second gas or second gas mixture in the second cavity being set, the first connection step taking place chronologically before the second connection step. The method according to the present invention has the advantage over those which are known from the related art that it dispenses with getter materials, to implement a second gas pressure in the second cavity which differs from the first gas pressure in the first cavity. The first connection step is implemented in a first atmosphere, which includes the first gas pressure and the first gas or gas mixture, and the second connection step is implemented in a second atmosphere, which includes the second gas pressure and the second gas or gas mixture. In one preferred specific embodiment, the first gas or gas mixture corresponds to the second gas or gas mixture. In addition to the costs which are saved (by omitting getter materials), it has proven to be a further advantage of the method according to the present invention for manufacturing a micromechanical device that it is not necessary to heat the micromechanical device to activate the getter material, whereby the risk of temperature-related irreversible damage of one of the components of the micromechanical device is dispensed with.

In one alternative specific embodiment, a connection, which implements an electrical contact between intermediate wafer and evaluation wafer or sensor wafer, is used for the first connection step and/or the second connection step. With the aid of the contacts and an electrically conductive signal path, which the intermediate wafer has, electrical signals may be transmitted from the sensor wafer via the electrical contact to the evaluation wafer (preferably for evaluating the signals from the sensor system) or from the evaluation wafer via the electrical contact to the sensor wafer (for example, to drive the seismic mass). It thus results that the signal path between evaluation wafer and sensor wafer is short in comparison to those which are known from the related art for micromechanical devices. An electrically conductive signal path is thus implemented, which is particularly advantageously less susceptible to interference in relation to electromagnetic radiation and parasitic capacitances in comparison to those micromechanical devices in which the electrical signals are transmitted via a longer signal path. In addition, the short signal paths contribute to the micromechanical device not being enlarged.

In one particularly preferred specific embodiment, the electrical contact between intermediate wafer and evaluation wafer or sensor wafer is a eutectic AlGe connection. For such a eutectic AlGe connection, it is provided that an aluminum (Al) layer or a layer which is essentially made of aluminum is situated on the sensor wafer and/or the evaluation wafer on the sides facing toward the intermediate wafer, this layer applied to the sensor wafer or evaluation wafer advantageously being accompanied by the advantage of being compatible with known sacrificial layer etching methods (HF gas phase etching) or methods for depositing anti-adhesive layers. In addition, the aluminum layer may fulfill the task of an etch stop layer. A germanium (Ge) layer is situated on the intermediate wafer for the eutectic AlGe connection, the germanium layer being deposited, tempered, purified, and conditioned on the intermediate wafer at high temperatures, to improve the connection properties, without influencing the sensitive sensor elements. In one preferred specific embodiment, the germanium layer or the aluminum layer is applied to a silicon underlay or layer, whereby silicon may diffuse during the first and/or second connection step(s) into the eutectic AlGe connection and increase the melting temperature. A self-stabilizing system thus advantageously results, which is also still stable at temperatures above the eutectic temperature of AlGe. The silicon layer under the germanium layer is preferably selected to be thinner during the second connection step, to keep the melting temperature for the second connection step lower than for the first connection step, which advantageously prevents the AlGe connection of the first connection step from melting again during the second connection step and therefore causing weakening or shifting of the AlGe connection of the first connection step.

In one preferred specific embodiment of the present invention, the intermediate wafer has pre-structuring, i.e., the intermediate wafer already has recesses or stops before the first connection step, which are situated both on the side facing toward the evaluation wafer and on the side facing toward the sensor wafer and, after the first connection step, are part of the first cavity and/or the second cavity. On the one hand, stops in the first and/or the second cavity are used, for example, to prevent spring fractures of the seismic mass. On the other hand, convexities or recesses in the area of the first and/or the second cavity ensure that a certain movement freedom is guaranteed or made available to the sensor element. In addition, the advantage results that the internal pressure in the first and/or the second cavity may be reliably set with the aid of the recesses or convexities, even if degassing occurs during the first connection step and/or the second connection step.

In another preferred specific embodiment of the present invention, the intermediate wafer is structured after the first connection step and before the second connection step. This structuring preferably implements, using simple means, the opening in the intermediate layer, which is responsible for a small access to the second cavity. In addition, this structuring has the advantage that, in a simple way, parts of the intermediate wafer may be insulated from one another, whereby conduction paths form after the second connection step.

In another preferred specific embodiment of the present invention, the intermediate wafer is structured with the aid of an etching method, preferably using an anisotropic etching step or a trenching step. Trenches are etched around the electrical contacts in the intermediate wafer, to implement a ventilation access to the second cavity and insulate the electrical contacts from the intermediate wafer, whereby freestanding stamps (or small rods) arise in the intermediate wafer, which are mechanically coupled to the sensor wafer. If an aluminum layer was situated on the sensor wafer, it may advantageously act as an etch stop layer and partially prevent the etching into the sensor wafer. The AlGe connection, which implements the electrical contact between sensor wafer and intermediate wafer, is preferably smaller than the mechanical connection of the sensor wafer to a sensor system, which includes the sensor element. The advantage thus results that mechanical stress influences are reduced, which originate from the AlGe connection or from the stamp, after intermediate wafer, evaluation wafer, and sensor wafer have been layered one on top of another. In one alternative specific embodiment of the present invention, evaluation wafer and intermediate wafer include printed conductors, which are exposed with the aid of the etching method and via which the electrical signals may be conducted to the sensor structure. This may advantageously contribute to the reduction of the occurring mechanical stresses in the micromechanical device.

In another preferred specific embodiment of the present invention, the intermediate wafer is ground on the side opposite the sensor wafer after the first connection step, to make it thinner. Using a thin intermediate wafer, not only is the signal path shortened, but rather the extension of the micromechanical device in a direction perpendicular to the main plane of extension is advantageously reduced in comparison to the case in which the intermediate wafer is not ground thin. The extension of the micromechanical device may be reduced further, in that the evaluation wafer is ground thin on the side opposite the intermediate wafer after the second method step.

### BRIEF DESCRIPTION OF THE DRAWINGS

FIG. 1 shows a schematic view of a micromechanical device according to a first specific embodiment.

FIG. 2 shows a schematic view of a micromechanical device according to a second specific embodiment.

FIG. 3 shows a schematic view of a micromechanical device according to a third specific embodiment.

FIGS. 4 through 7 show a method for manufacturing a micromechanical device.

### DETAILED DESCRIPTION OF THE INVENTION

In the various figures, identical parts are always provided with identical reference numerals and are therefore generally also only cited or mentioned once in each case.

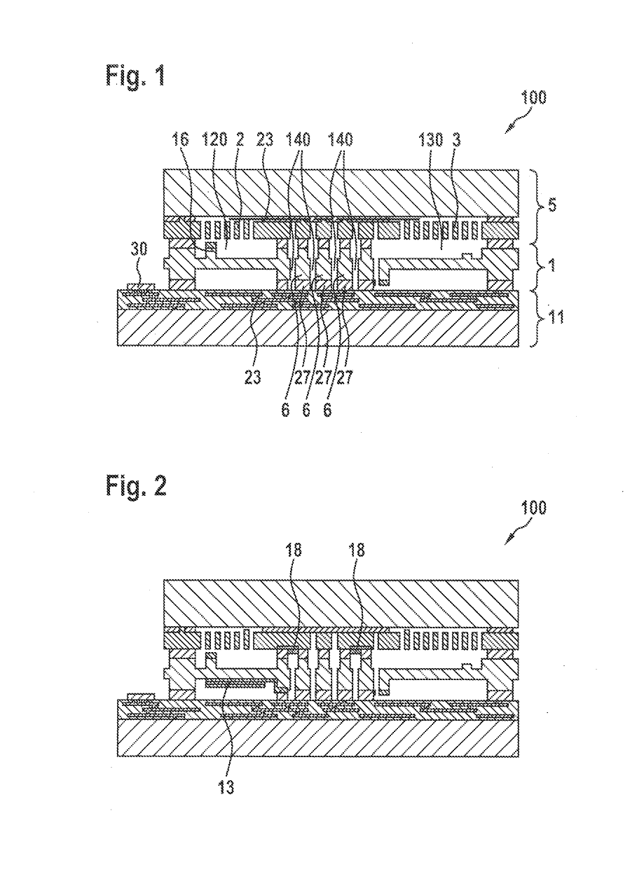

FIG. 1 shows a first specific embodiment according to the present invention of a micromechanical device 100. It includes an intermediate wafer 1, an evaluation wafer 11, and a sensor wafer 5, which have a shared main plane of extension and are stacked in such a way that intermediate wafer 1 is situated between evaluation wafer 11 and sensor wafer 5. In the specific embodiment shown, a first sensor element 2 and a second sensor element 3 are part of sensor wafer 5. First sensor element 2 and second sensor element 3 are preferably seismic masses, which are each part of a sensor system, such a micromechanical device 100 being able to include a plurality of (in this specific embodiment two) sensor elements 3. In particular, first sensor element 2 is part of an acceleration sensor and second sensor element 3 is part of a rotation rate sensor. A first cavity 120, which contains first sensor element 2, has, according to the present invention, a different pressure than a second cavity 130, which contains second sensor element 3. Alternatively, a first atmosphere in first cavity 120 may also differ from a second atmosphere in second cavity 130. Preferably, first and/or second cavity 120 and/or 130 include(s) one or multiple stops 16, which are provided, for example, to prevent spring fractures of the seismic mass in the event of an overload. In the illustrated specific embodiment according to the present invention of micromechanical device 100, intermediate wafer 1 includes openings or interruptions 140, which are situated in such a way that they are, inter alia, an integral part of second cavity 130. In addition, connection parts 6, which are insulated from one another, and which connect evaluation wafer 11 and sensor wafer 5, may form due to openings or interruptions 140. The connection parts may also be situated inside the second cavity. If intermediate wafer 1 is made of an electrically conductive material, these connection parts 6 form conductor paths, via which evaluation wafer 11 and sensor wafer 5 are electrically conductively connected to one another, if an electrical contact 27 is provided for an electrical connection between intermediate wafer 1 and evaluation wafer 11 or sensor wafer 5. In particular, conductor paths 6 may also electrically conductively connect printed conductors 23, which are provided in evaluation wafer 11 or sensor wafer 5, to one another, one or multiple printed conductors 23 in sensor wafer 5 being electrically conductively connected to the sensor system, and one or multiple printed conductors 23 in evaluation wafer 11 being electrically conductively connected to an application-specific integrated circuit, which is an integral part of evaluation wafer 11.

With the aid of electrically conductive conductor paths 6 and printed conductors 23, electrical signals may be transmitted from the sensor system to the application-specific integrated circuit. To connect micromechanical device 100 in an electrically conductive way to a circuit board or a carrier for micromechanical devices, a bond pad 30 is provided on the evaluation wafer.

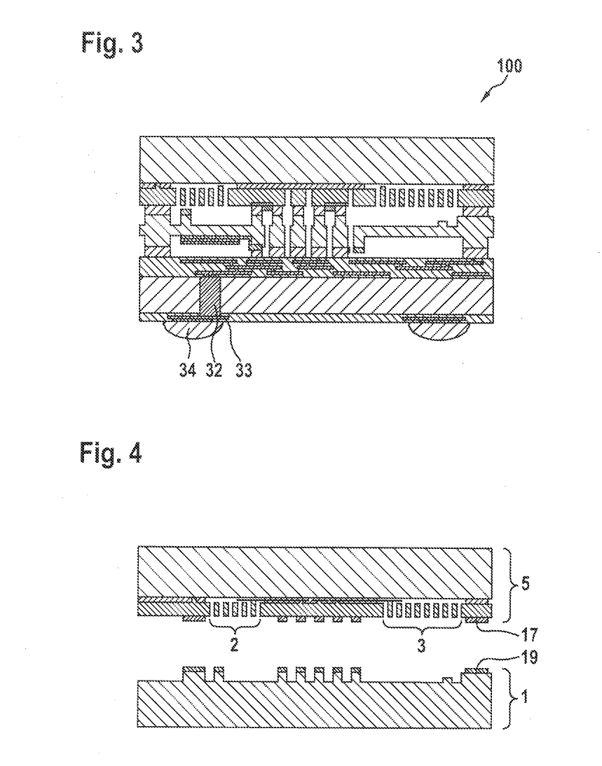

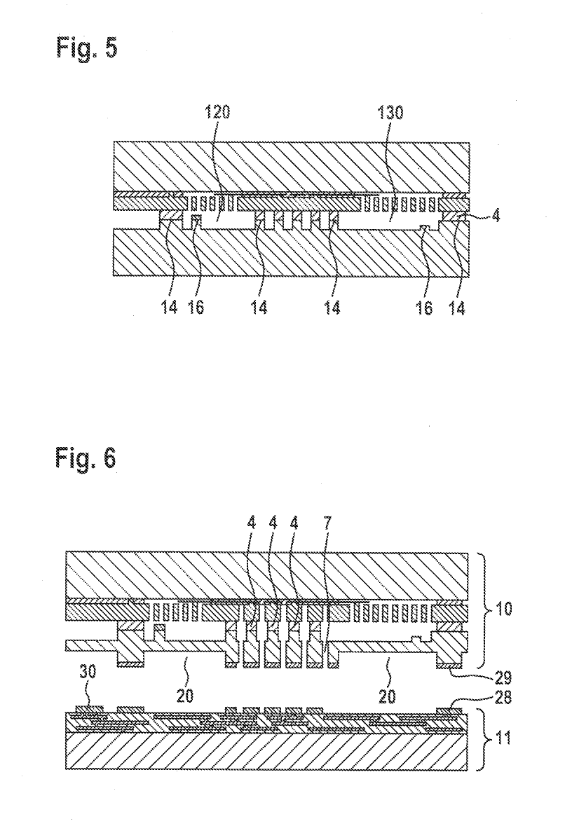

The micromechanical devices according to the second and third specific embodiments of the present invention shown in FIG. 2 and FIG. 3 have essentially the same features as the micromechanical device according to the first specific embodiment. Therefore, the description of the parts which were already described in FIG. 1 will be avoided or simplified.

FIG. 2 shows a second specific embodiment according to the present invention of a micromechanical device 100. In comparison to the first specific embodiment of the present invention, it has the feature that a sensor means 13 is situated on the intermediate wafer, on the side facing toward the evaluation wafer. Sensor means 13 may be a further sensor system, in particular a sensor means 13, or a passive element. Sensor means 13 is preferably a magnetic field sensor. Independently of this sensor means 13, micromechanical device 100 according to the second specific embodiment has an etch stop layer 18, which is provided on sensor wafer 5, to prevent etching of sensor wafer 5 during the manufacturing process of micromechanical device 100. This is generally a layer including aluminum for this purpose.

FIG. 3 shows a second specific embodiment according to the present invention of a micromechanical device 100. In this specific embodiment, the electrical terminal, which electrically conductively connects micromechanical device 100 to a circuit board, for example, is a solder ball 34, which is situated on evaluation wafer 11 on the side facing away from intermediate wafer 1. To connect solder ball 34 in an electrically conductive way to printed conductors 23 or the evaluation-oriented circuits, one or multiple through silicon vias (TSV) 32, which are connected via a wiring level 33 to solder ball 34, are provided in evaluation wafer 11. This specific embodiment has the advantage that micromechanical device 100 may be situated directly on the circuit board in the sense of a bare die structure, the packaging of micromechanical device 100, which is linked to additional costs, being able to be omitted. Through vias 32 are preferably filled or partially filled with metal and are insulated from the silicon of the evaluation wafer by an insulation layer.

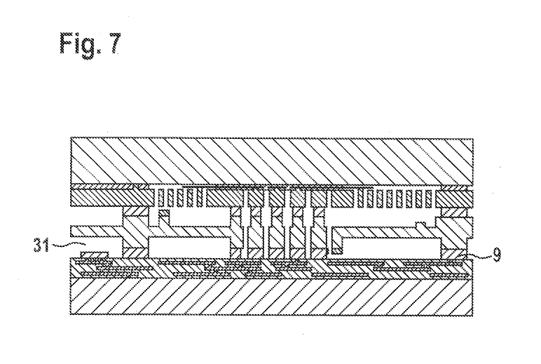

FIGS. 4 through 7 show individual manufacturing steps for manufacturing a micromechanical device 100 according to the present invention. FIG. 4 shows a sensor wafer 5 and an intermediate wafer 1, before they are connected to one another in a first connection step. Sensor wafer 5 includes a first sensor element 2 and a second sensor element 3. In addition, sensor wafer 5 has a printed conductor 23, which is electrically conductively connected to a sensor system, the sensor system including first sensor element 2 or third sensor element 3. It is provided that the electrical signal from the sensor system is conducted via printed conductor 23 to an electrical contact, which is to electrically conductively connect intermediate wafer 1 to sensor wafer 5. For this purpose, sensor wafer 5 preferably has a first aluminum (Al) layer 17 at the points provided for the electrical contact. In addition, sensor wafer 5 is preferably equipped with a first aluminum layer 17 at those points, at which a further, possibly solely mechanical connection is planned between intermediate wafer 1 and sensor wafer 5, for example, for the hermetic closure of the intermediate wafer with the sensor wafer. Therefore, a first coating pattern is implemented on sensor wafer 5 on the side facing toward intermediate wafer 1. Intermediate wafer 1 has a second coating pattern, which is situated congruently or approximately congruently to the first coating pattern on the side facing toward sensor wafer 5 and is preferably made of first germanium (Ge) layers 19. In particular, it is possible that intermediate wafer 1 is structured, the structure corresponding to the second coating pattern and including ridges of the intermediate wafer which face toward sensor wafer 5. In the specific embodiment shown, intermediate wafer 1 has further ridges in addition to the second coating pattern. In following FIGS. 5 through 7, each of the features or components described in the preceding figure are supplemented with further components or further features. Therefore, in FIGS. 5 through 7, the features or components of the micromechanical device which are already known from the preceding figure are not described in detail again. FIG. 5 shows how intermediate wafer 1 and evaluation wafer 5 are connected to one another via a first AlGe connection 4 after a first connection step, the connections being located at the points at which the first coating pattern is congruent with the second coating pattern. If the intermediate wafer has a structure at these points, it is referred to hereafter as a ridge of first type 14. All further structures on the side of the intermediate wafer facing toward the sensor wafer are referred to hereafter as ridges of the second type and generally form stops 16, which are preferably provided to prevent a spring fracture of the seismic mass in the event of an overload. A first cavity 120 and a second cavity 130, which both have a first gas pressure, are produced by the first connection step.

FIG. 6 shows an evaluation wafer 11 and an intermediate wafer-sensor wafer stack 10 before a second connection step. Intermediate wafer-sensor wafer stack 10 includes intermediate wafer 1 and sensor wafer 5 after it (i.e., intermediate wafer-sensor wafer stack 10) has been structured. In general, an anisotropic etching method is provided for the structuring, which induces openings or interruptions in the intermediate wafer, whereby the intermediate wafer has individual isolated points, i.e., small rods/stamps, which are linked via AlGe connection 4 to sensor wafer 5. In one preferred specific embodiment, the anisotropic etching method also etches into the sensor wafer, whereby printed conductors are exposed which are possibly situated in the sensor wafer. It is additionally provided according to the present invention that one of the openings or interruptions caused by the etching method, for example, forms a small access 7. A second gas pressure in the second cavity will then generally no longer correspond to the first gas pressure in the first cavity, for which a small access is not provided.

Before the second connection step is completed, intermediate wafer 1 may be structured on its side facing toward evaluation wafer 11, whereby recesses 20 result, for example. A sensor means could be situated in these recesses, for example.

To complete the second connection step, the intermediate wafer has a third coating pattern, on the side facing away from sensor wafer 5, which is preferably made of a second germanium (Ge) layer 29. A germanium layer 29 is to be located on each of the small rods of the intermediate wafer. The third coating pattern is congruent or approximately congruent with a fourth coating pattern applied to the evaluation wafer, the coating pattern being made of second aluminum (Al) layers. Evaluation wafer 11 additionally includes a bond pad 30, via which the micromechanical device may preferably establish the electrical contact to a circuit board.

FIG. 7 shows a micromechanical device after the second connection step, intermediate wafer 1 and evaluation wafer 11 being connected to one another via a second AlGe connection 9. The gas pressure in the second cavity generally differs from that in the first cavity, because the second cavity could assume the ambient gas pressure via the small access during the second connection step. In one alternative specific embodiment, the second cavity accommodates a second atmosphere (having a second type of gas or a second gas mixture) during the first connection step, which differs from a first atmosphere (having a first type of gas or a first gas mixture), which has been accommodated by the first cavity during the first connection step.

In addition, in the specific embodiment shown, micromechanical device 100 has a germanium etching 31 of the intermediate wafer, whereby a cavity is implemented above bond pad 30. In this specific embodiment, it is possible to expose bond pads 30 without damage during a sawing process.

1-16. (canceled)

17. A micromechanical device, comprising:
a sensor wafer;
an intermediate wafer; and
an evaluation wafer;
wherein:
the micromechanical device has a main plane of extension;
the sensor wafer, the intermediate wafer, and the evaluation wafer are stacked in such a way that the intermediate wafer is situated between the sensor wafer and the evaluation wafer;
the evaluation wafer has at least one application-specific integrated circuit;
at least one of the sensor wafer and the intermediate wafer includes a first sensor element;
at least one of the sensor wafer and the intermediate wafer includes a second sensor element which is spatially separated from the first sensor element;
the first sensor element is located in a first cavity which is formed by the intermediate wafer and the sensor wafer;
the second sensor element is located in a second cavity which is formed by the intermediate wafer and the sensor wafer;
a first gas pressure in the first cavity differs from a second gas pressure in the second cavity; and
the intermediate wafer has at least one opening at at least one point in a direction extending perpendicularly to the main plane of extension.

18. The micromechanical device as recited in claim 17, wherein the at least one opening is situated between the second cavity and the evaluation wafer.

19. The micromechanical device as recited in claim 18, wherein the intermediate wafer is electrically conductive, and the sensor wafer and the evaluation wafer are conductively connected to one another via the intermediate wafer.

20. The micromechanical device as recited in claim 19, wherein one of a first gas or a first gas mixture in the first cavity differs from one of a second gas or a second gas mixture in the second cavity.

21. The micromechanical device as recited in claim 19, wherein one of:
the first sensor element is part of an acceleration sensor and the second sensor element is part of a rotation rate sensor; or
the first sensor element is part of a rotation rate sensor and the second sensor element is part of an acceleration sensor.

22. The micromechanical device as recited in claim 19, wherein a sensor unit is provided on the intermediate wafer, the sensor unit including a sensor element and a passive element.

23. The micromechanical device as recited in claim 19, wherein at least one of the first cavity and the second cavity includes at least one of a stop and an anti-adhesive layer.

24. The micromechanical device as recited in claim 19, wherein:
the sensor wafer includes at least one first printed conductor; and
the evaluation wafer includes at least one second printed conductor; and
the at least one first printed conductor of the sensor wafer is conductively connected to the at least one second printed conductor of the evaluation wafer via the intermediate wafer.

25. The micromechanical device as recited in claim 19, wherein an electrical terminal is situated on the evaluation wafer, on one of (i) the side of the evaluation wafer facing toward the intermediate wafer or (ii) the side of the evaluation wafer facing away from the intermediate wafer.

26. A method for manufacturing a micromechanical device including a sensor wafer, an intermediate wafer, and an evaluation wafer, wherein the micromechanical device has a main plane of extension; the sensor wafer, the intermediate wafer, and the evaluation wafer are stacked in such a way that the intermediate wafer is situated between the sensor wafer and the evaluation wafer; the evaluation wafer has at least one application-specific integrated circuit; at least one of the sensor wafer and the intermediate wafer includes a first sensor element; at least one of the sensor wafer and the intermediate wafer includes a second sensor element which is spatially separated from the first sensor element; the first sensor element is located in a first cavity which is formed by the intermediate wafer and the sensor wafer; the second sensor element is located in a second cavity which is formed by the intermediate wafer and the sensor wafer; a first gas pressure in the first cavity differs from a second gas pressure in the second cavity; and the intermediate wafer has at least one opening at at least one point in a direction extending perpendicularly to the main plane of extension, the method comprising:
connecting the sensor wafer and the intermediate wafer to one another in a first connection step; and
connecting the intermediate wafer and the evaluation wafer to one another in a second connection step chronologically following the first connection step;
wherein the first gas pressure of the first gas in the first cavity is set during the first connection step and the second gas pressure of the second gas in the second cavity is set during the second connection step.

27. The method as recited in claim 26, wherein at least one of (i) the first connection step achieves an electrical contact between the sensor wafer and the intermediate wafer, and (ii) the second connection step achieves an electrical contact between the intermediate wafer and the evaluation wafer, the intermediate wafer being electrically conductive.

28. The method as recited in claim 27, wherein a eutectic AlGe connection is used to form at least one of (i) the electrical contact between the intermediate wafer and the evaluation wafer, and (ii) the electrical contact between the intermediate wafer and the sensor wafer.

29. The method as recited in claim 27, wherein, before the first and the second connection steps, the intermediate wafer is provided with at least one of a recess and a stop on at least one of the side facing toward the sensor wafer and the side facing toward the evaluation circuit wafer.

30. The method as recited in claim 27, wherein the intermediate wafer is structured between the first connection step and the second connection step.

31. The method as recited in claim 30, wherein at least one of (i) an etching method is used for structuring the intermediate wafer, and (ii) the etching method exposes printed conductors situated in the sensor wafer.

32. The method as recited in claim 27, wherein, after the first connection step, the intermediate wafer is ground and, after the second connection step, the micromechanical device is ground.
